(19) United States
(12) Patent Application Publication
(10) Pub. No.: US 2025/0254966 A1
(43) Pub. Date: Aug. 7, 2025

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Tetsuo TAKAHASHI, Tokyo (JP)

(73) Assignee: Mitsubishi Electric Corporation, Tokyo (JP)

(21) Appl. No.: 18/830,131

(22) Filed: Sep. 10, 2024

(30) Foreign Application Priority Data
Feb. 5, 2024 (JP) 2024-015648

(51) Int. Cl. H01L 29/423; H01L 29/49

(52) U.S. Cl. CPC H10D 64/519; H10D 64/664

(57) ABSTRACT

A semiconductor device according to the present disclosure, includes a semiconductor substrate; a gate electrode which is provided above the semiconductor substrate with a gate insulating film intervening between the gate electrode and the semiconductor substrate and is made with polysilicon; a first metal layer which is provided on the gate electrode; a second metal layer which is provided on the first metal layer; a first electrode which is provided above the second metal layer with an interlayer insulating film intervening between the first electrode and the second metal layer; and a second electrode which is provided on an opposite side of the semiconductor substrate from the first electrode, wherein at least one of the first metal layer and the second metal layer contains a metal which suppresses movement of a movable ion.

### BACKGROUND

### Field

The present disclosure relates to a semiconductor device and a method for manufacturing the semiconductor device.

### Background

JP 2008-218808 A discloses a structure in which a polycide layer made of WSi, a barrier metal layer made of WN, a metal layer made of W, and an insulating-film hard mask layer made of SiN are stacked in this order on a gate electrode.

A semiconductor device for power called a power device is generally used in, e.g., a switching device which controls power supply for a motor load or the like. One of requirements for a power device is reduction in loss. Reduction in loss of a power device produces effects, such as reduction in device size and reduction in weight, and may lead to friendliness to the global environment in a broad sense. Additionally, these characteristics are required to be achieved at the lowest possible cost.

As a power semiconductor device which meets the above-described requirements, an insulated gate semiconductor device, such as an IGBT (Insulated Gate Bipolar Transistor) or a MOSFET (Metal Oxide Semiconductor Field Effect Transistor), is widely used. In recent years, a MOSFET, an IGBT, or the like using a wide-bandgap semiconductor, such as silicon carbide (SiC), has been proposed. A MOSFET using silicon carbide is a device which can achieve both a low on-resistance and maintenance of a high main withstand voltage. Since the MOSFET is a monopolar device, the MOSFET has an increasing range of uses for high-speed switching.

In a semiconductor device as described above, a gate electrode may be made with polysilicon. Although a polysilicon electrode is easy to form in a wafer process, the polysilicon electrode has lower conductivity than a metal layer. Thus, a delay in signal transmission due to a high polysilicon wiring resistance in an active region, i.e., a high parasitic resistance may interfere with speed-up in switching.

JP 2008-218808 A discloses a technique for forming a low-resistance metal layer on polysilicon to lower a wiring resistance. However, further speed-up is becoming necessary. Semiconductor devices using silicon carbide have been found to have a plurality of problems, i.e., a gate characteristic shift, such as a threshold shift due to AC stress, and increase in cost due to increase in the number of man-hours. These problems may manifest themselves at the time of application of high-speed switching.

### SUMMARY

The present disclosure has been made to solve the above-described problems, and has as its object to obtain a semiconductor device capable of reducing a gate wiring resistance and suppressing a threshold shift and a method for manufacturing the semiconductor device.

The features and advantages of the present disclosure may be summarized as follows.

According to an aspect of the present disclosure, a semiconductor device includes a semiconductor substrate; a gate electrode which is provided above the semiconductor substrate with a gate insulating film intervening between the gate electrode and the semiconductor substrate and is made with polysilicon; a first metal layer which is provided on the gate electrode; a second metal layer which is provided on the first metal layer; a first electrode which is provided above the second metal layer with an interlayer insulating film intervening between the first electrode and the second metal layer; and a second electrode which is provided on an opposite side of the semiconductor substrate from the first electrode, wherein at least one of the first metal layer and the second metal layer contains a metal which suppresses movement of a movable ion.

According to an aspect of the present disclosure, a method for manufacturing a semiconductor device includes forming a gate electrode above a semiconductor substrate with a gate insulating film intervening between the gate electrode and the semiconductor substrate, using polysilicon; forming a first metal layer on the gate electrode; forming a second metal layer on the first metal layer; forming a first electrode above the second metal layer with an interlayer insulating film intervening between the first electrode and the second metal layer; and forming a second electrode on an opposite side of the semiconductor substrate from the first electrode, wherein at least one of the first metal layer and the second metal layer contains a metal which suppresses movement of a movable ion.

Other and further objects, features and advantages of the disclosure will appear more fully from the following description.

### BRIEF DESCRIPTION OF DRAWINGS

FIG. 1 is a plan view of a semiconductor device according to a first embodiment.

FIG. 2 is a plan view of the active region according to the first embodiment.

FIG. 3 is a sectional view taken along line A-A′ of the semiconductor device according to the first embodiment.

FIG. 4 is a plan view of the peripheral portion according to the first embodiment.

FIG. 5 is a sectional view taken along line B-B′ of the semiconductor device according to the first embodiment.

FIGS. 6 to 29 are views for explaining the method for manufacturing the semiconductor device according to the first embodiment.

FIG. 30 is a sectional view taken along line A-A′ of a semiconductor device according to a second embodiment.

FIG. 31 is a sectional view taken along line B-B′ of the semiconductor device according to the second embodiment.

FIG. 32 is a sectional view taken along line A-A′ of a semiconductor device according to a third embodiment.

FIG. 33 is a sectional view taken along line B-B′ of the semiconductor device according to the third embodiment.

FIG. 34 is a sectional view taken along line A-A′ of a semiconductor device according to a fourth embodiment.

FIG. 35 is a sectional view taken along line B-B′ of the semiconductor device according to the fourth embodiment.

FIGS. 36 to 43 are views for explaining a method for manufacturing the semiconductor device according to the fourth embodiment.

FIG. 44 is a sectional view taken along line A-A′ of a semiconductor device according to a fifth embodiment.

FIG. 45 is a sectional view taken along line A-A′ of a semiconductor device according to a sixth embodiment.

FIG. 46 is a plan view of a semiconductor device according to a comparative example.

FIG. 47 is a plan view of the active region according to the comparative example.

FIG. 48 is a sectional view taken along line A-A′ of the semiconductor device according to the comparative example.

FIG. 49 is a plan view of the peripheral portion according to the comparative example.

FIG. 50 is a sectional view taken along line B-B′ of the semiconductor device according to the comparative example.

### DESCRIPTION OF EMBODIMENTS

A semiconductor device and a method for manufacturing the semiconductor device according to each embodiment will be described with reference to the accompanying drawings. Components identical or corresponding to each other are indicated by the same reference characters, and repeated description of them is avoided in some cases.

### First Embodiment

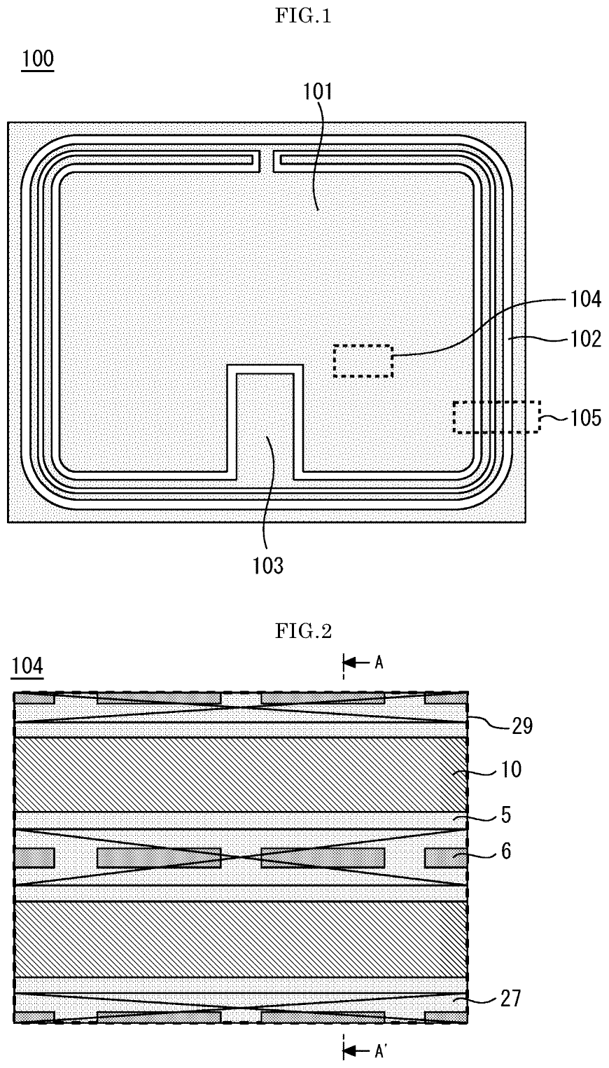

FIG. 1 is a plan view of a semiconductor device 100 according to a first embodiment. The semiconductor device 100 is, for example, a power semiconductor device used for power. FIG. 1 shows the whole of an device region of the semiconductor device 100. The semiconductor device 100 includes an active region 101, a peripheral portion 102 around the active region 101, and a gate pad region 103 which is a control electrode. The peripheral portion 102 has a gate wiring region and a withstand voltage maintenance region.

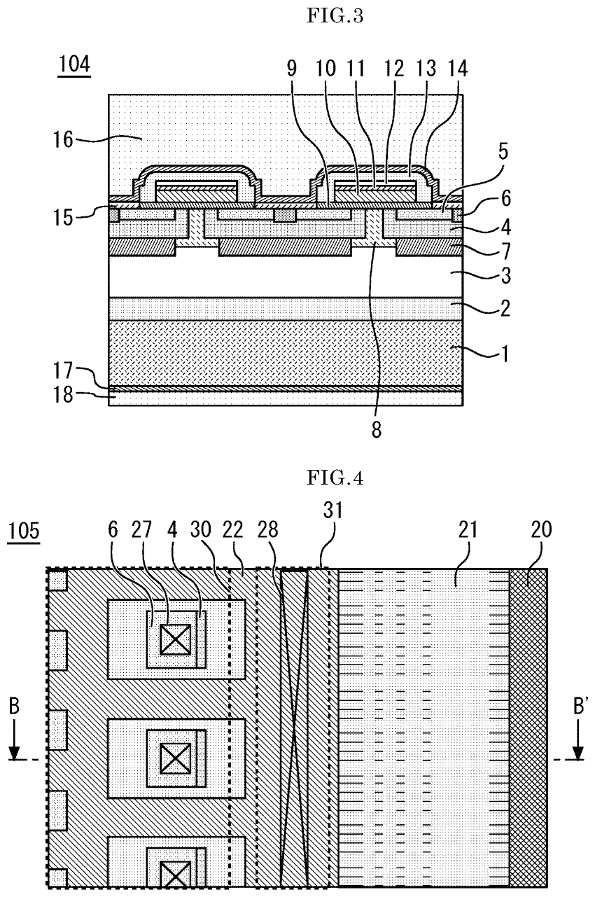

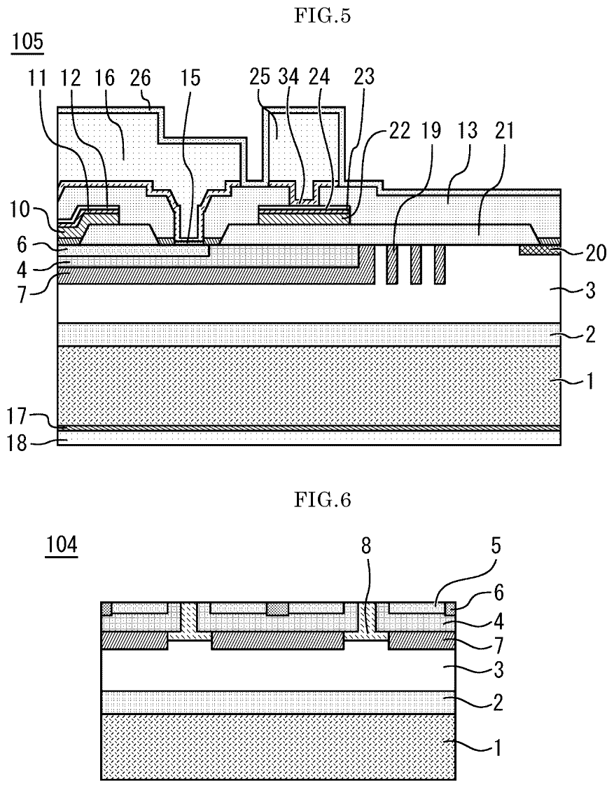

FIG. 2 is a plan view of the active region 101 according to the first embodiment. FIG. 2 is an enlarged view of a region 104 in FIG. 1. FIG. 3 is a sectional view taken along line A-A′ of the semiconductor device 100 according to the first embodiment. FIG. 4 is an enlarged view of a region 105 in FIG. 1. FIG. 5 is a sectional view taken along line B-B′ of the semiconductor device 100 according to the first embodiment.

The semiconductor device 100 includes an n⁺ substrate 1. An n⁺ buffer layer 2 is provided on an upper surface side of the substrate 1. An n drift layer 3 is provided on an upper surface side of the buffer layer 2. A p-channel doped layer 4 is provided on an upper surface side of the drift layer 3. An n⁺ source layer 5 and a p⁺ contact layer 6 are provided on an upper surface side of the channel doped layer 4. A p well layer 7 is provided between the drift layer 3 and the channel doped layer 4. An n-JFET doped layer 8 is provided between the channel doped layers 4 and between the well layers 7. The substrate 1, the buffer layer 2, the drift layer 3, the channel doped layers 4, the source layers 5, the contact layers 6, the well layers 7, and the JFET doped layers 8 may hereinafter be collectively called a semiconductor substrate.

In the active region 101, a gate electrode 10 is provided above the semiconductor substrate with a gate insulating film 9 intervening therebetween. The gate electrode 10 is made with polysilicon. A first metal layer 11 is provided on the gate electrode 10. The first metal layer 11 is made out of, for example, Ti silicide and is also called a gate silicide metal layer. A second metal layer 12 is provided on the first metal layer 11. The second metal layer 12 is made out of, for example, TiN and is also called a low-resistance barrier metal layer.

A barrier metal layer 14 is provided above the second metal layer 12 with an interlayer insulating film 13 intervening therebetween. A source electrode 16 which is a first electrode is provided on the barrier metal layer 14. A silicide layer 15 is provided on a portion exposed from the gate insulating film 9 of an upper surface of the semiconductor substrate. The barrier metal layer 14 and the source electrode 16 cover the interlayer insulating film 13 and the silicide layer 15. A drain electrode 18 which is a second electrode is provided on the opposite side of the semiconductor substrate from the source electrode 16 with a silicide layer 17 intervening therebetween.

In the peripheral portion 102, a p-FLR diffusion layer 19 and an n-channel stopper layer 20 are provided on the upper surface side of the drift layer 3. In the withstand voltage maintenance region, the FLR diffusion layers 19 and the channel stopper layer 20 form an FLR (Field Limiting Ring) structure. In the peripheral portion 102, a field insulating film 21 is provided on the upper surface of the semiconductor substrate. On the field insulating film 21, a gate wiring layer 22 which is made out of polysilicon, a first metal layer 23, and a second metal layer 24 are stacked, as in the active region 101. A barrier metal layer 34 and a gate wiring layer 25 are stacked on the second metal layer 24. The gate wiring layer 25 is electrically connected to the second metal layer 24. The barrier metal layer 34 is in contact with the second metal layer 24 and connects the gate wiring layer 25 and the second metal layer 24 together. A passivation insulating film 26 is provided on the gate wiring layer 25 and the source electrode 16.

Regions denoted by x in FIGS. 2 and 4 indicate source contact regions 27 and a gate contact region 28. The source contact region 27 is a portion where the source electrode 16 and the semiconductor substrate are electrically connected. The gate contact region 28 is a portion where the gate wiring layer 25 and a gate electrode structure including the gate wiring layer 22, the first metal layer 23, and the second metal layer 24 are electrically connected. Regions surrounded by dotted lines in FIGS. 2 and 4 indicate source metal regions 29 and 30 and a gate metal region 31. As shown in FIGS. 4 and 5, the gate wiring layer 25 is provided farther from a center of the semiconductor substrate than, of the source contact regions 27, a portion farthest from a center of the active region 101 is.

A principal current flows from the source electrode 16 to the drain electrode 18, i.e., in a substrate vertical direction in FIG. 3. The current is gate-controlled by a MOSFET composed of the source layer 5, the channel doped layer 4, the drift layer 3, the gate insulating film 9, and the gate electrode 10. As shown in FIG. 2, unit cells are formed in a striped pattern, and the gate electrodes 10 are also formed in a striped pattern. The gate electrode 10 is connected to the gate wiring layer 25 shown in FIG. 5 at an end of the active region 101 and is connected to the gate pad region 103 via the gate contact region 28 and the gate metal region 31.

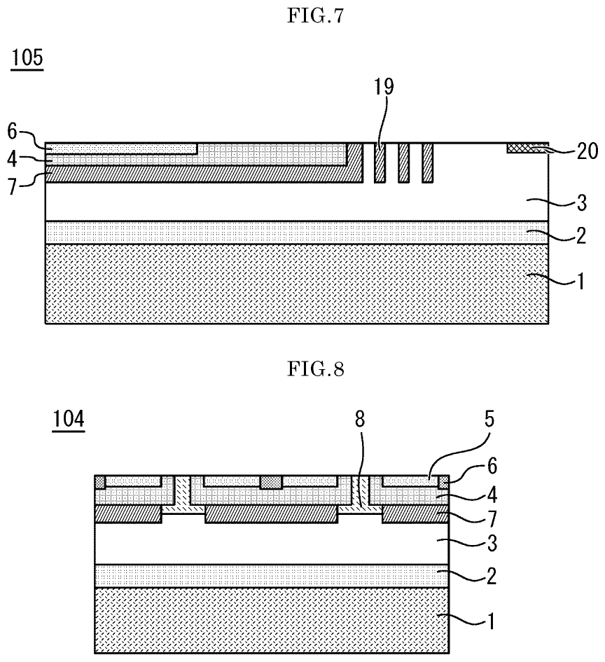

A method for manufacturing the semiconductor device 100 of the present embodiment will be described. FIGS. 6 to 29 are views for explaining the method for manufacturing the semiconductor device 100 according to the first embodiment. FIGS. 6 and 7 are a sectional view taken along line A-A′ of the region 104 and a sectional view taken along line B-B′ of the region 105, respectively, showing a state where introduction of impurities at predetermined positions and activation are completed. Since steps thus far can be executed using a general manufacturing process, a description thereof will be omitted.

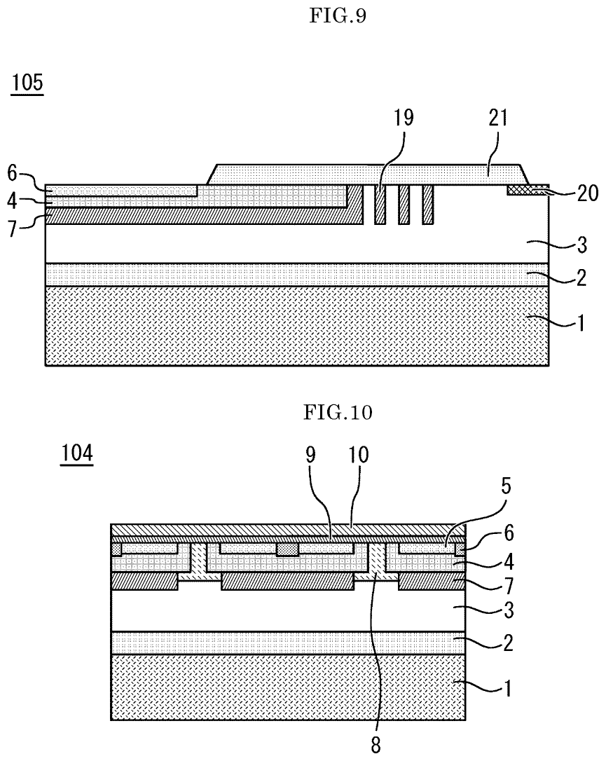

The field insulating film 21 is formed at the peripheral portion 102. FIGS. 8 and 9 are a sectional view taken along line A-A′ and a sectional view taken along line B-B′, respectively, in a state where the field insulating film 21 is formed.

The gate electrode 10 is formed above the semiconductor substrate with the gate insulating film 9 intervening therebetween, using polysilicon. FIGS. 10 and 11 are a sectional view taken along line A-A′ and a sectional view taken along line B-B′, respectively, in a state where the gate insulating film 9 and the gate electrode 10 are formed. The gate insulating film 9 can be formed using an approach, such as thermal oxidation or oxide film deposition. A polysilicon layer which is to serve as the gate electrode 10 can be formed by depositing doped polysilicon highly doped with P (phosphorus) by a method, such as CVD (Chemical Vapor Deposition). A doped polysilicon concentration is adjusted so as to be approximately not less than 10¹⁹/cm³. The gate electrode 10 is formed to have a thickness of about 2000 to 10000 Å. The gate electrode 10 is set to a thickness which prevents a polysilicon layer from being lost at the time of silicide film formation in a subsequent step.

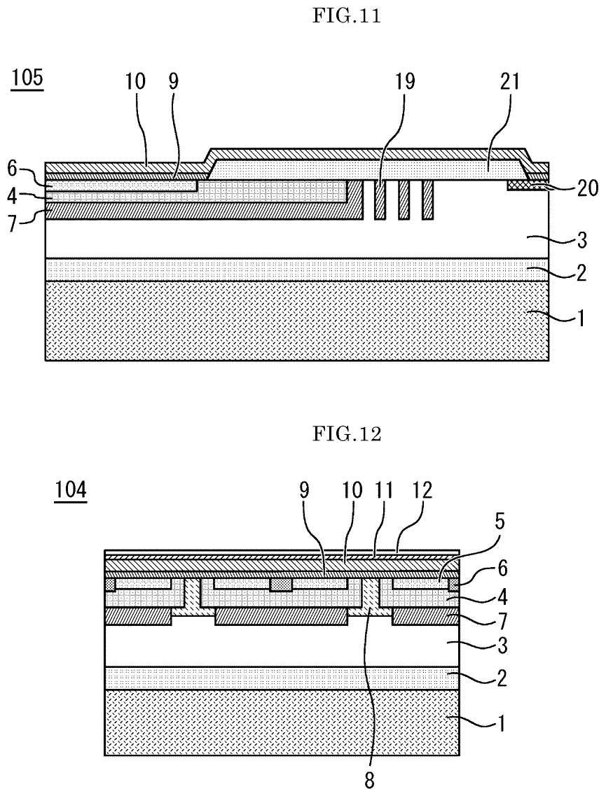

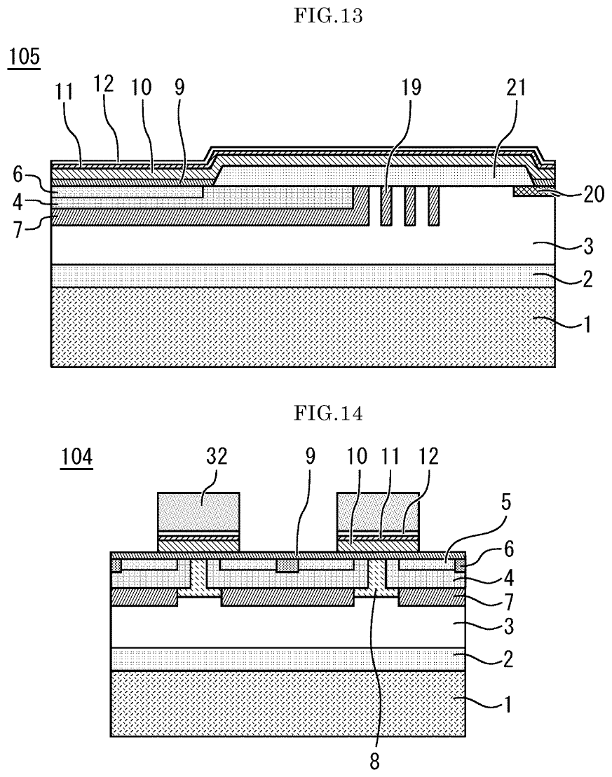

The first metal layer 11 is formed on the gate electrode 10, and the second metal layer 12 is formed on the first metal layer 11. FIGS. 12 and 13 are a sectional view taken along line A-A′ and a sectional view taken along line B-B′, respectively, in a state where the first metal layer 11 and the second metal layer 12 are formed. First, Ti is deposited on the gate electrode 10 by a method, such as sputtering. A thickness of the Ti layer is sufficient if the thickness is about 200 to 2000 Å. A TiN layer is then deposited by a method, such as sputtering. Annealing, such as lamp annealing, is further performed, thereby forming, on the gate electrode 10, the first metal layer 11 that is a gate silicide metal layer where silicide (TiSix) and Ti are coexistent and the second metal layer 12 that is a low-resistance barrier metal layer made out of TiN.

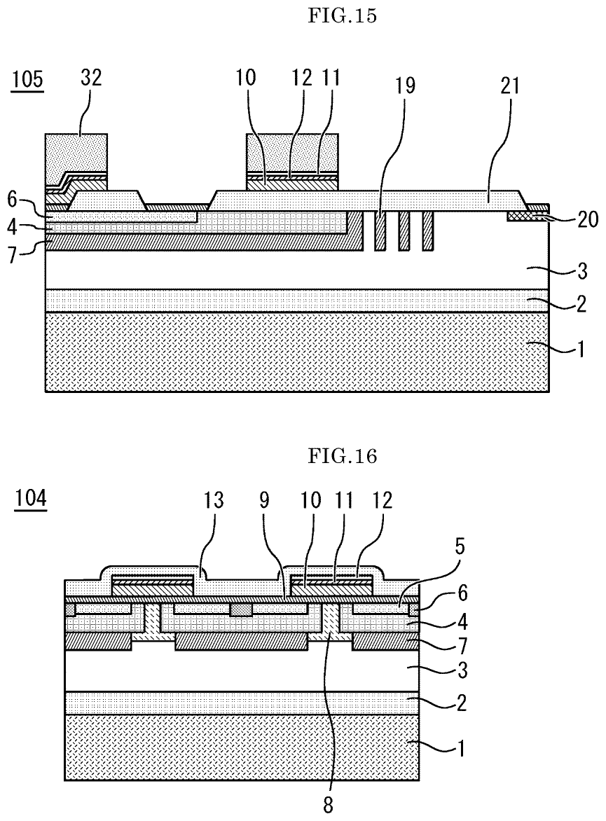

A resist 32 is applied onto the first metal layer 11 and the second metal layer 12, and patterning is performed by a general photolithography step. FIGS. 14 and 15 are a sectional view taken along line A-A′ and a sectional view taken along line B-B′, respectively, in a state where the gate electrode 10, the first metal layer 11, and the second metal layer 12 are patterned. In the patterning, the gate electrode 10, the first metal layer 11, and the second metal layer 12 are etched in a predetermined pattern by, for example, two-step dry etching.

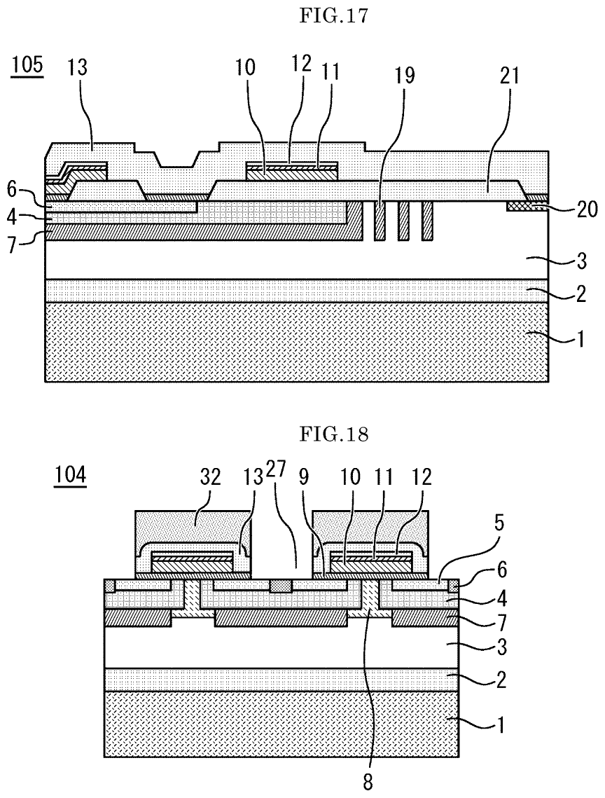

The interlayer insulating film 13 is deposited using, e.g., a CVD system. FIGS. 16 and 17 are a sectional view taken along line A-A′ and a sectional view taken along line B-B′, respectively, in a state where the interlayer insulating film 13 is formed. The interlayer insulating film 13 can be formed using, for example, TEOS (Tetraethylorthosilicate) or BPSG (Borophosphosilicate glass). The interlayer insulating film 13 may be stacked to a thickness of about 5000 to 20000 Å in consideration of thicknesses of the gate electrode 10, the first metal layer 11 and the second metal layer 12.

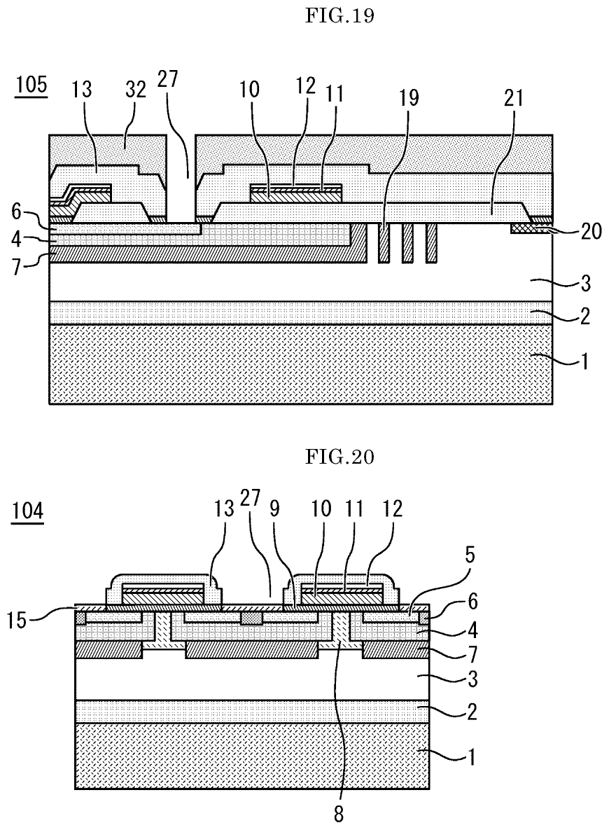

The source contact region 27 is formed using a general photolithography step. FIGS. 18 and 19 are a sectional view taken along line A-A′ and a sectional view taken along line B-B′, respectively, in a state where the source contact regions 27 are formed. The source contact region 27 can be formed by making an opening in the interlayer insulating film 13 using a method, such as dry etching.

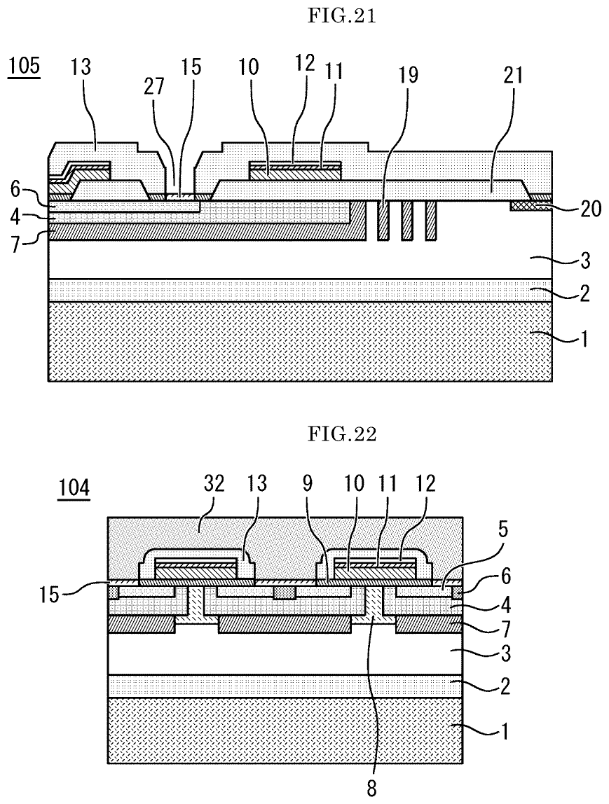

The silicide layer 15 is formed in the opening of the source contact region 27. FIGS. 20 and 21 are a sectional view taken along line A-A′ and a sectional view taken along line B-B′, respectively, in a state where the silicide layers 15 are formed. First, a metal material, such as Ni, is deposited on an SiC surface by a method, such as sputtering, and is subjected to annealing treatment at about 800 to 1100° C. After that, an unnecessary metal material is removed, thereby forming the silicide layer 15.

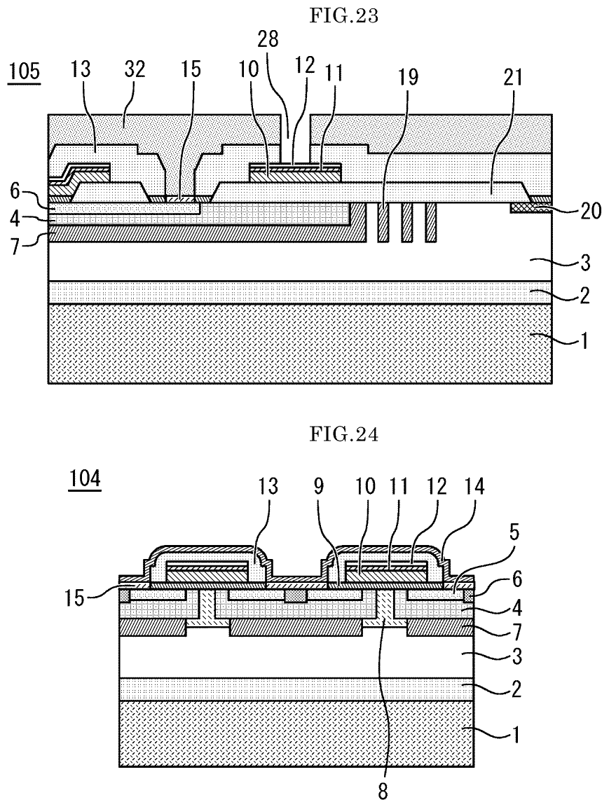

The gate contact region 28 is formed using, e.g., a general photolithography technique. FIGS. 22 and 23 are a sectional view taken along line A-A′ and a sectional view taken along line B-B′, respectively, in a state where the gate contact region 28 is formed. The gate contact region 28 can be formed by exposing a predetermined position of a gate electrode structure by a method, such as dry etching, in a state where the gate electrode structure except the predetermined position is protected with the resist 32.

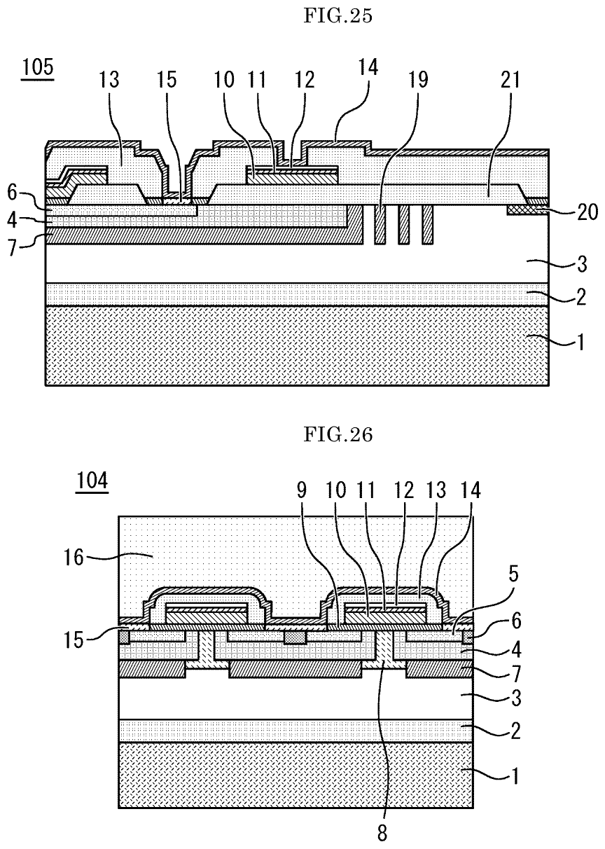

The barrier metal layer 14 is deposited in the gate contact region 28 and on the interlayer insulating film 13. FIGS. 24 and 25 are a sectional view taken along line A-A′ and a sectional view taken along line B-B′, respectively, in a state where the barrier metal layer 14 is formed. Ti, TiN, Ti and TiN in two tiers, or the like may be used for the barrier metal layer 14. The barrier metal layer 14 can be formed by deposition by a method, such as sputtering. A thickness of the barrier metal layer 14 is sufficient if the thickness is about 200 to 2000 Å.

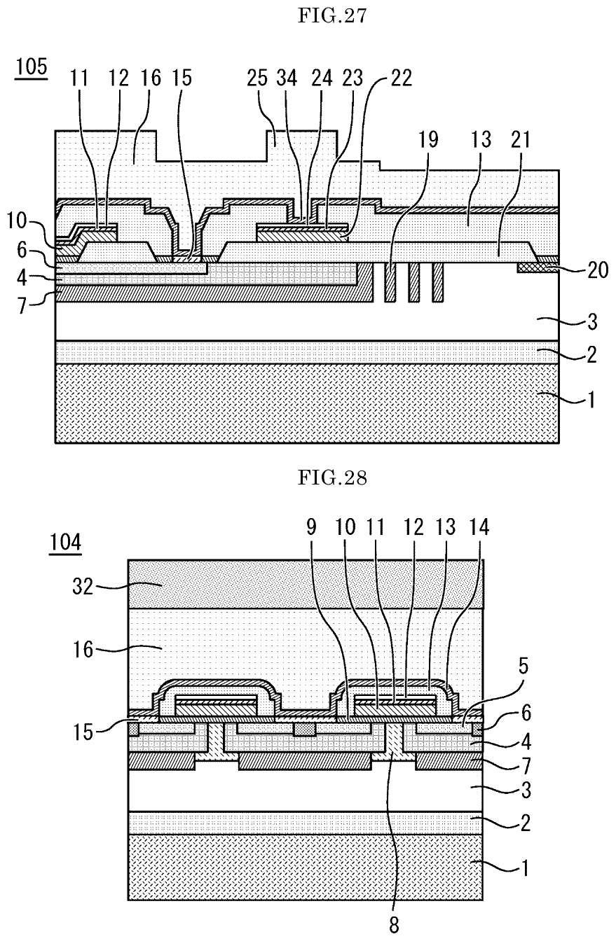

The source electrode 16 and the gate wiring layer 25 are formed. FIGS. 26 and 27 are a sectional view taken along line A-A′ and a sectional view taken along line B-B′, respectively, in a state where the source electrode 16 and the gate wiring layer 25 are formed. The source electrode 16 and the gate wiring layer 25 may be simultaneously formed. A metal, such as AlSi, AlSiCu, AlCu, or Al, or the like can be used for the source electrode 16 and the gate wiring layer 25. The source electrode 16 and the gate wiring layer 25 can be formed by deposition by a method, such as sputtering. Thicknesses of the source electrode 16 and the gate wiring layer 25 differ depending on the purpose and may be 0.8 to 10 μm. As can be seen from the foregoing, the barrier metal layer 14 and the source electrode 16 are formed above the second metal layer 12 with the interlayer insulating film 13 intervening therebetween. Note that the gate electrode 10, the first metal layer 11, the second metal layer 12, and the barrier metal layer 14 at the peripheral portion 102 may be referred to as the gate wiring layer 22, the first metal layer 23, the second metal layer 24, and the barrier metal layer 34.

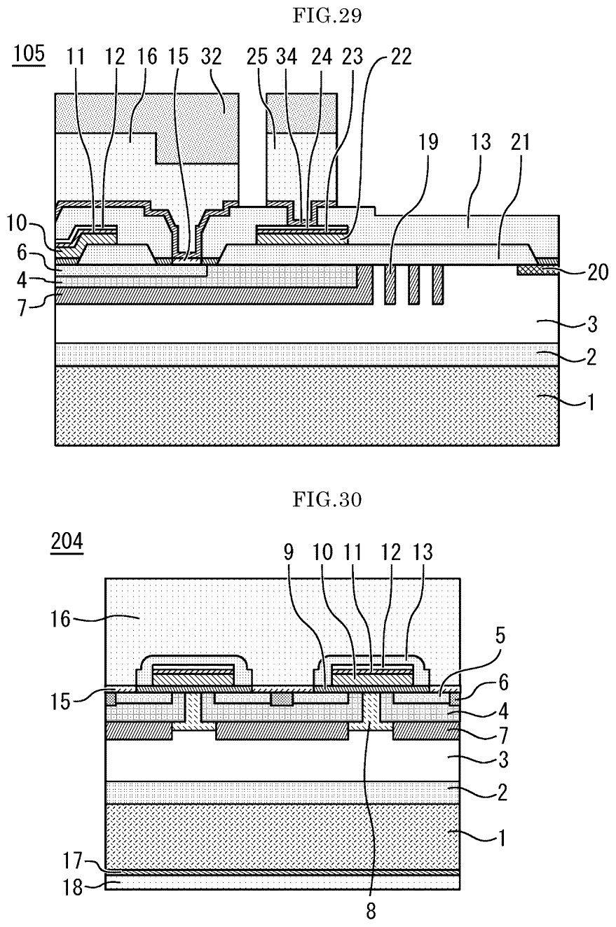

The barrier metal layer 34, the source electrode 16, and the gate wiring layer 25 are etched using a predetermined photolithography technique. FIGS. 28 and 29 are a sectional view taken along line A-A′ and a sectional view taken along line B-B′, respectively, in a state where the electrode is etched. The semiconductor device 100 can be formed by steps, such as forming the second electrode on the opposite side of the semiconductor substrate from the first electrode after that. Since such steps can be performed using a general method for manufacturing a semiconductor device, a description thereof will be omitted.

Operation of the semiconductor device 100 will be described. When a positive voltage applied to the gate pad region 103 becomes not less than a threshold voltage for a MOSFET, each MOSFET is turned on to reduce a drain voltage, and a principal current flows between a source and a drain to put the semiconductor device 100 in an on state. On the other hand, when a negative voltage is applied to the gate pad region 103 in the on state and becomes not more than the threshold voltage, each MOSFET is turned off to cut off the current between the source and the drain, and the drain voltage rises to put the semiconductor device 100 in an off state.

FIG. 46 is a plan view of a semiconductor device 800 according to a comparative example. The semiconductor device 800 includes an active region 801, a peripheral portion 802 around the active region 801, and a gate pad region 803. The peripheral portion 802 has a gate wiring region and a withstand voltage maintenance region.

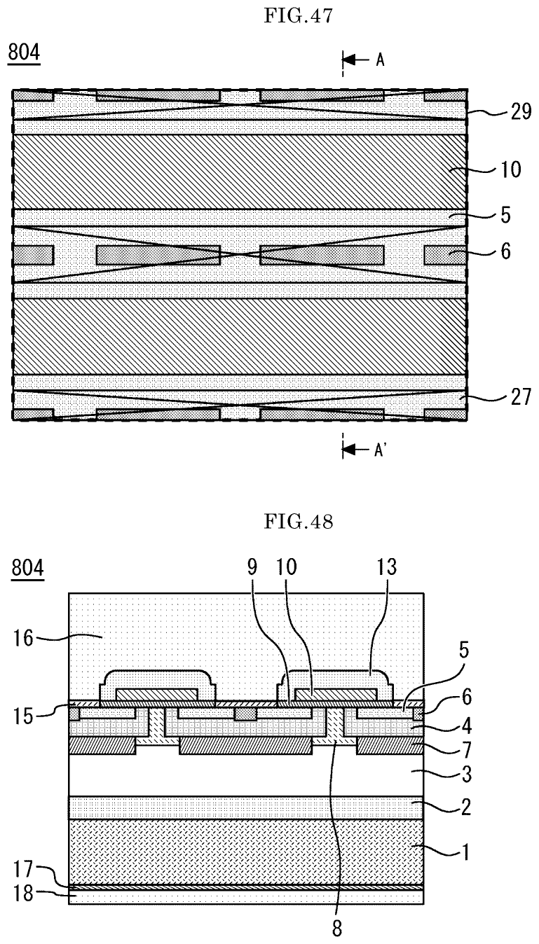

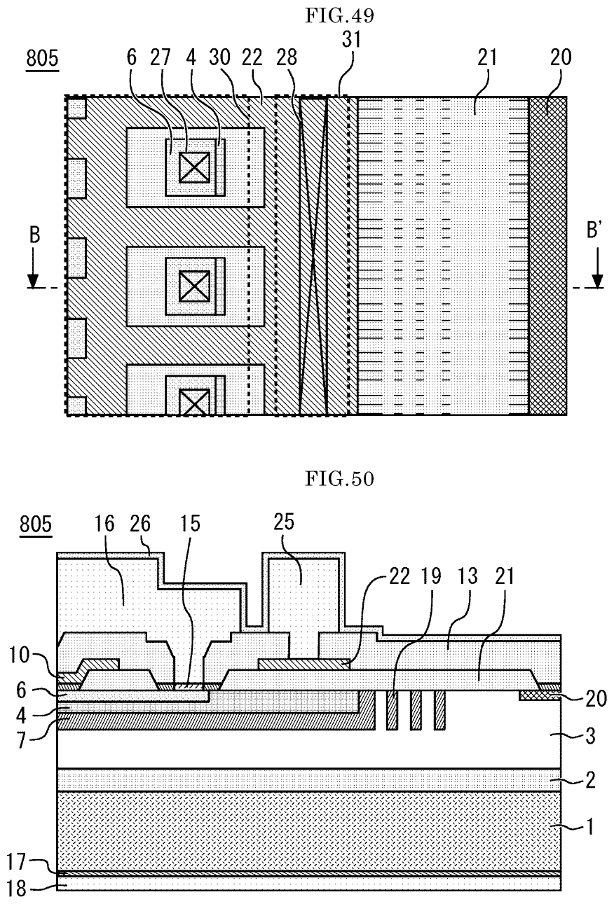

FIG. 47 is a plan view of the active region 801 according to the comparative example. FIG. 47 is an enlarged view of a region 804 in FIG. 46. FIG. 48 is a sectional view taken along line A-A′ of the semiconductor device 800 according to the comparative example. FIG. 49 is an enlarged view of a region 805 in FIG. 46. FIG. 50 is a sectional view taken along line B-B′ of the semiconductor device 800 according to the comparative example.

A gate electrode 10 of the semiconductor device 800 according to the comparative example is made with polysilicon, as in the semiconductor device 100 according to the first embodiment. The semiconductor device 800 is different from the semiconductor device 100 in that first metal layers 11 and 23, second metal layers 12 and 24, and barrier metal layers 14 and 34 are not provided. Other components are the same as those of the semiconductor device 100.

As shown in FIG. 47, the semiconductor device 800 is paved with cells in a striped pattern or in a grid pattern. The gate electrode 10 is connected to the gate pad region 803 via a gate wiring layer 22 and a gate wiring layer 25 at an end of the active region 801. In this case, there is a delay from when a signal is input to the gate pad region 803 to when a voltage of each unit sell in the active region 801 exceeds a threshold voltage to turn on or turn off the unit cell.

A unit cell at a farthest position from the gate pad region 803 is turned on or turned off latest. This is because of a time constant determined by an input capacitance of the semiconductor device 800 and a wiring parasitic resistance. As a parasitic resistance increases, a time constant increases, and a delay time becomes longer. Since a parasitic resistance connected in series to a gate increases with increase in a distance between the gate pad region 803 and a cell, a delay time becomes longer.

The higher a resistance of the gate electrode 10 in the active region 801 is, the higher a time constant is and the more difficult high-speed driving is. Although a polysilicon electrode is easy to form in a wafer process, the polysilicon electrode has lower conductivity than a metal layer. As described above, a delay in signal transmission due to a high polysilicon wiring resistance may interfere with speed-up in switching.

In contrast, in the present embodiment, the first metal layer 11 and the second metal layer 12 that are lower in resistance than polysilicon are provided on the gate electrode 10. The first metal layer 11 and the second metal layer 12 are provided with a plurality of functions. First, the first metal layer 11 and the second metal layer 12 allow reduction in gate wiring resistance. Resistivity of a metal is generally about 1/10 to 1/1000 that of polysilicon, depending on the concentration of polysilicon, the type of metal, and the like. For this reason, in the present embodiment, a parasitic resistance can be largely reduced as compared with the semiconductor device 800 of the comparative example.

A gate electrode structure including the gate electrode 10, the first metal layer 11, and the second metal layer 12 is extended to the peripheral portion 102 around the active region 101. That is, the gate electrode structure including the gate wiring layer 22, the first metal layer 23, and the second metal layer 24 are electrically connected to the gate wiring layer 25 at the peripheral portion 102. This allows further reduction in resistance of gate wiring.

The semiconductor device 100 includes, above the second metal layer 24, the gate wiring layer 25 that is electrically connected to the second metal layer 24 and contains Al. If the gate electrode 10 containing Si reacts with the gate wiring layer 25 containing Al, a problem of, e.g., Al spikes may occur. To cope with this, the second metal layer 24 made out of TiN lies between the gate electrode 10 and the gate wiring layer 25 in the present embodiment. For this reason, generation of Al spikes can be suppressed. That is, the second metal layer 24 can be made to function as a barrier metal. The second metal layers 12 and 24 are not limited to TiN and may be metal layers which do not contain Si.

The first metal layer 11 and the second metal layer 12 contain Ti that is a metal which suppresses movement of movable ions. If a movable ion reaches, from an upper portion of the active region 101, an interface between the gate insulating film 9 that determines a main characteristic of a gate and the channel doped layer 4, a characteristic, such as a threshold voltage, may fluctuate. To cope with this, the first metal layer 11 and the second metal layer 12 contain a metal which suppresses movement of movable ions in the present embodiment. Suppression of movable ion permeation allows suppression of a threshold shift. Thus, according to the present embodiment, high-speed switching is made possible by suppressing a threshold shift while reducing a gate wiring resistance.

A movable ion is, for example, a hydrogen ion which gains entry from a mold of a product. Hydrogen can be trapped by Ti. The first metal layer 11 and the second metal layer 12 may be made out of a metal other than Ti as long as the metal can suppress movement of movable ions. It is only necessary that at least one of the first metal layer 11 and the second metal layer 12 contain a metal which suppresses movement of movable ions.

In the present embodiment, the barrier metal layer 14 is formed so as to cover the interlayer insulating film 13. That is, the barrier metal layer 14 containing a metal which suppresses movement of movable ions is included between the interlayer insulating film 13 and the source electrode 16. This allows further suppression of movable ion permeation.

In the present embodiment, a surface on the opposite side of the second metal layer 12 from the semiconductor substrate is fully covered with the interlayer insulating film 13 in the active region 101. The second metal layer 24 at the peripheral portion 102 is also fully covered with the interlayer insulating film 13 except a portion in contact with the gate wiring layer 25. This allows reduction in resistance of the gate metal region 31 and enhancement of flexibility in wiring. Also, metal corrosion due to, e.g., moisture absorption can be suppressed.

In the example shown in FIGS. 4 and 5, the gate contact region 28 is arranged beside the source contact region 27 while the source contact region 27 is secured for potential stability of the end of the active region 101. In this case, a width of the gate contact region 28 needs to be locally reduced. In the present embodiment, however, two or more layers of metal layers including the first metal layer 23 and the second metal layer 24 are formed on the gate wiring layer 22. It is thus possible to ensure flexibility in the design of gate and source patterns while preventing increase in parasitic resistance by covering low-resistance gate wiring with the interlayer insulating film 13.

The first metal layer 11 and the second metal layer 12 may be provided on a part of an upper surface of the gate electrode 10 of doped polysilicon or may be provided on the whole. The first metal layer 11 and the second metal layer 12 may be made out of Ni, Co, W, or the like instead of Ti. Such metal layers also allow reduction in gate wiring resistance and suppression of generation of Al spikes.

The semiconductor substrate of the present embodiment may be an Si substrate or may be made with a wide-bandgap semiconductor. The wide-bandgap semiconductor is, for example, silicon carbide, a GaN-based material, or diamond. As described above, since a threshold shift, in particular, becomes a problem in a semiconductor device using silicon carbide, the present embodiment can be effectively used.

Although the present embodiment has been described taking a MOSFET as an example, the present embodiment can be applied to every semiconductor device, in which a polysilicon electrode is provided above a semiconductor substrate with a gate insulating film intervening therebetween. For example, the present embodiment may be applied to an IGBT. The number of metal layers formed on the gate electrode 10 may be set to two or more.

These modifications can be appropriately applied to semiconductor devices and methods for manufacturing the semiconductor devices according to embodiments below. Meanwhile, for the semiconductor devices and the methods for manufacturing the semiconductor devices according to the embodiments below, dissimilarities with the first embodiment will mainly be explained as they have many similarities with the first embodiment.

### Second Embodiment

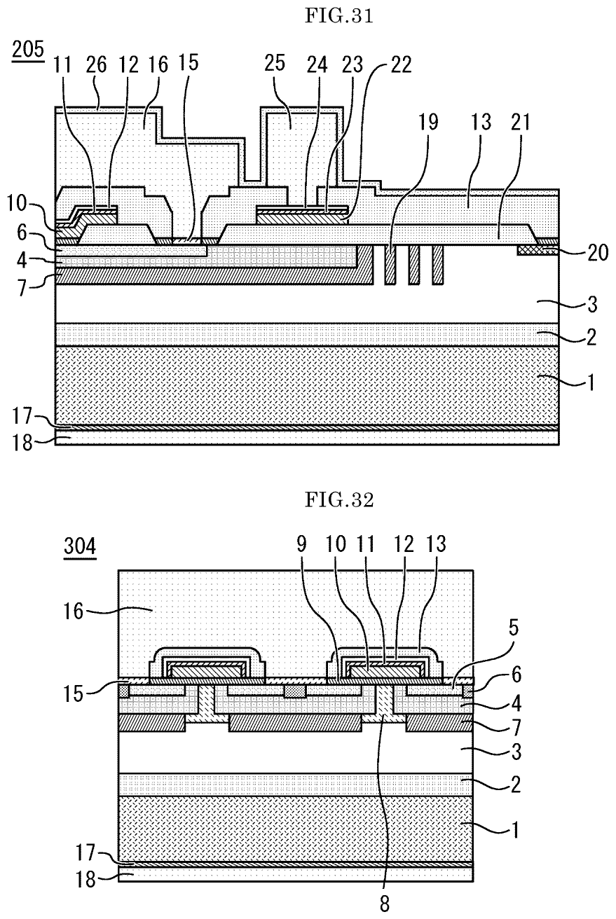

FIG. 30 is a sectional view taken along line A-A′ of a semiconductor device 100 according to a second embodiment. That is, FIG. 30 is a sectional view of a region 204 corresponding to the region 104 in the first embodiment. FIG. 31 is a sectional view taken along line B-B′ of the semiconductor device 100 according to the second embodiment. That is, FIG. 31 is a sectional view of a region 205 corresponding to the region 105 in the first embodiment. The present embodiment is different from the first embodiment in that barrier metal layers 14 and 34 are not provided. Other components are the same as those in the first embodiment. A method for manufacturing the semiconductor device 100 of the present embodiment can be implemented by omitting the steps shown in FIGS. 24 and 25.

Since barrier metal layers 14 and 34 are not provided in the present embodiment, the effect of suppressing permeation of movable ions is reduced as compared with the first embodiment. However, manufacturing steps can be simplified as compared with the first embodiment, and the semiconductor device 100 can be manufactured at a lower price.

### Third Embodiment

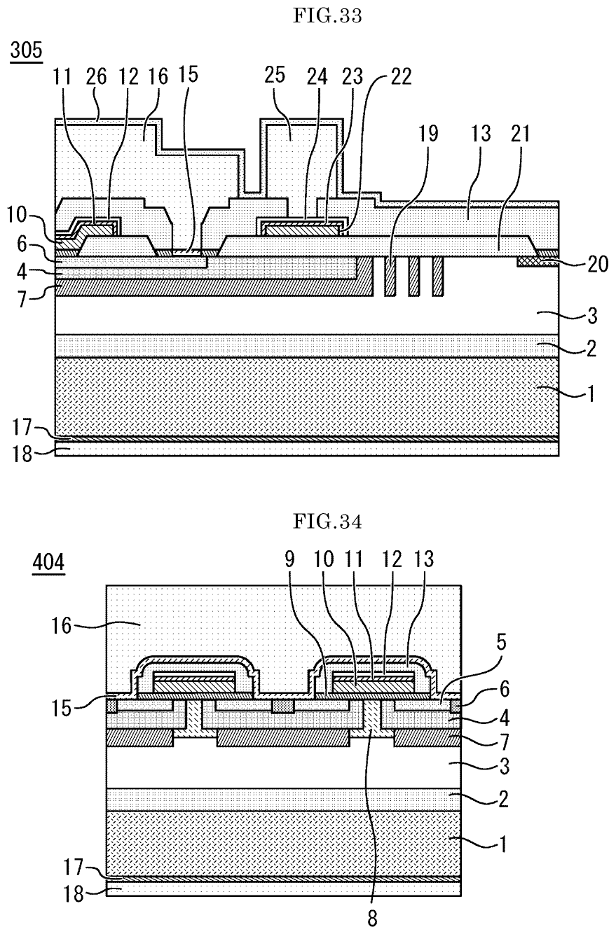

FIG. 32 is a sectional view taken along line A-A′ of a semiconductor device 100 according to a third embodiment. That is, FIG. 32 is a sectional view of a region 304 corresponding to the region 104 in the first embodiment. FIG. 33 is a sectional view taken along line B-B′ of the semiconductor device 100 according to the third embodiment. That is, FIG. 33 is a sectional view of a region 305 corresponding to the region 105 in the first embodiment. In the present embodiment, a surface on the opposite side from a semiconductor substrate and side surfaces of a gate electrode 10 are covered with a first metal layer 11 and a second metal layer 12. Other components are the same as those in the second embodiment.

The present embodiment allows strengthening of the effect of reducing a parasitic resistance of gate wiring and suppressing a threshold shift due to movable ion permeation.

### Fourth Embodiment

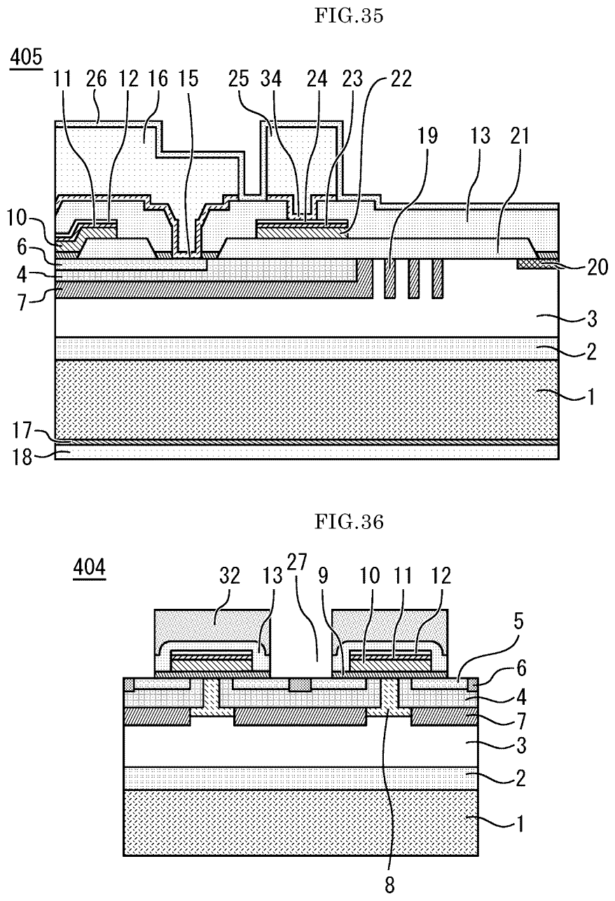

FIG. 34 is a sectional view taken along line A-A′ of a semiconductor device 100 according to a fourth embodiment. That is, FIG. 34 is a sectional view of a region 404 corresponding to the region 104 in the first embodiment. FIG. 35 is a sectional view taken along line B-B′ of the semiconductor device 100 according to the fourth embodiment. That is, FIG. 35 is a sectional view of a region 405 corresponding to the region 105 in the first embodiment. In the present embodiment, a barrier metal layer 34 which is in contact with a second metal layer 24 and connects a gate wiring layer 25 and the second metal layer 24 together and a silicide layer 15 which is a metal layer in contact with a semiconductor substrate and connecting a source electrode 16 and the semiconductor substrate together are made with the same metal. In an active region 101, the silicide layer 15 is formed on the whole of an upper surface of an interlayer insulating film 13. Other components are the same as those in the first embodiment.

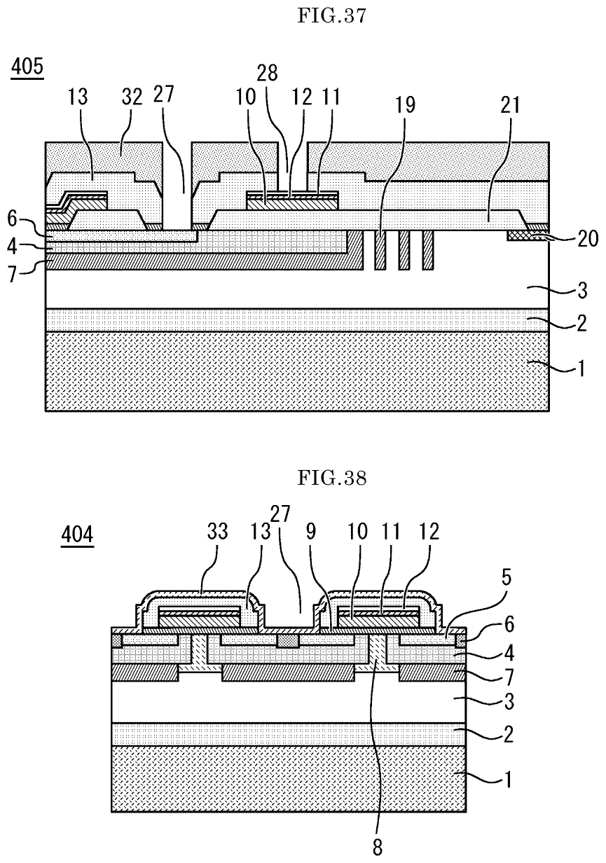

FIGS. 36 to 43 are views for explaining a method for manufacturing the semiconductor device 100 according to the fourth embodiment. The steps up to the ones shown in FIGS. 16 and 17 in the first embodiment are also adopted in the present embodiment. After a resist 32 is patterned using a photolithography technique, the interlayer insulating film 13 and a gate insulating film 9 are etched by a method, such as dry etching, to form source contact regions 27 and a gate contact region 28. FIGS. 36 and 37 are a sectional view taken along line A-A′ and a sectional view taken along line B-B′, respectively, in a state where the source contact regions 27 and the gate contact region 28 are formed.

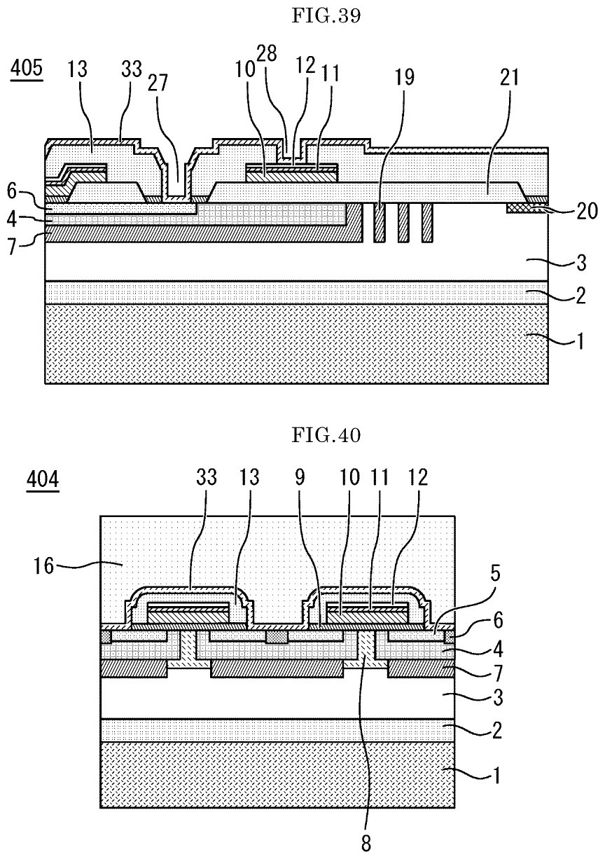

A metal layer 33 which is to serve as the silicide layer 15 and the barrier metal layer 34 is formed in the source contact regions 27 and the gate contact region 28, using a method, such as sputtering. A metal, such as Ni or Ti, is used for the metal layer 33. As described above, after a first metal layer 11 and a second metal layer 12 are formed, the metal layer 33 that is to come into contact with the semiconductor substrate to connect a first electrode and the semiconductor substrate together is formed. FIGS. 38 and 39 are a sectional view taken along line A-A′ and a sectional view taken along line B-B′, respectively, in a state where the metal layer 33 is formed.

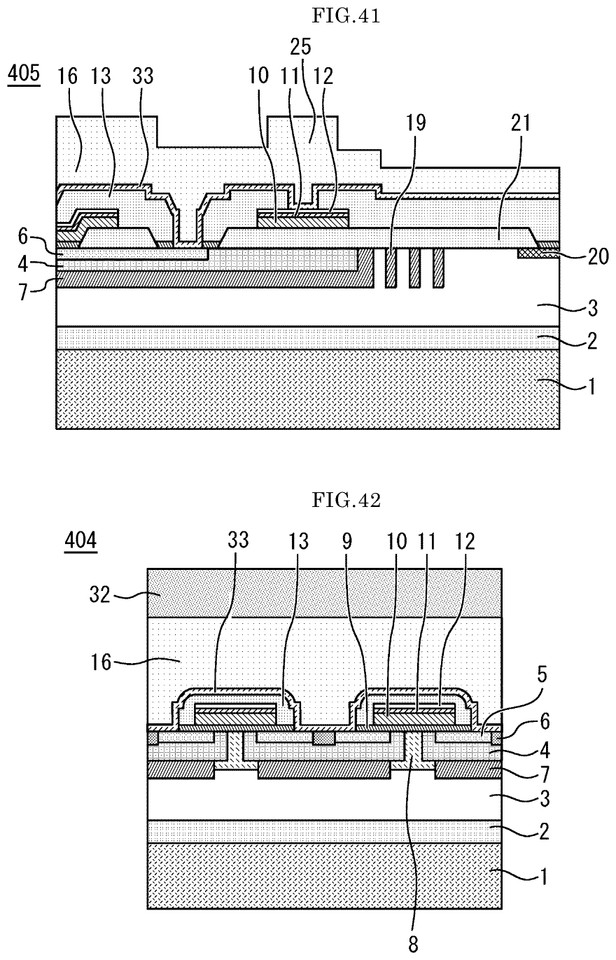

The source electrode 16 and the gate wiring layer 25 are formed. FIGS. 40 and 41 are a sectional view taken along line A-A′ and a sectional view taken along line B-B′, respectively, in a state where the source electrode 16 and the gate wiring layer 25 are formed. A metal, such as AlSi, AlSiCu, AlCu, or Al, may be used for the source electrode 16 and the gate wiring layer 25, as in the first embodiment.

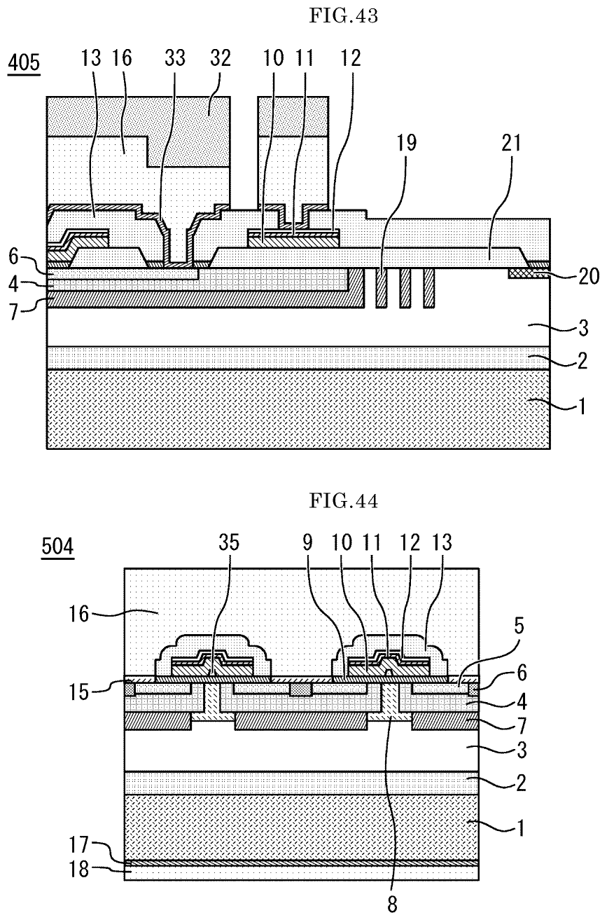

An electrode material is etched using a predetermined photolithography technique. FIGS. 42 and 43 are a sectional view taken along line A-A′ and a sectional view taken along line B-B′, respectively, in a state where the electrode material is etched. Since subsequent steps can be performed using a general method for manufacturing a semiconductor device, a description thereof will be omitted.

In the present embodiment, a material for the silicide layer 15 and a material for the barrier metal layer 14, 34 are the same. Manufacturing cost can be reduced by simultaneously forming the silicide layer 15 and the barrier metal layer 14, 34. If the silicide layer 15 and the barrier metal layer 14, 34 contain a metal which prevents movable ions of, e.g., Ti, a problem, such as a threshold shift due to permeation of movable ions, can be curbed by forming the barrier metal layer 14, 34 so as to cover the interlayer insulating film 13.

The silicide layer 15 and the barrier metal layer 14, 34 may contain Ni. If the semiconductor device 100 is formed using SiC, Ni is preferably used as a barrier metal for the SiC substrate in consideration of a work function. In this case, if a contact with an Ni layer is provided in polysilicon, a reaction may proceed too far. In the present embodiment, an overreaction of an Ni layer with polysilicon can be prevented by forming a first metal layer 23 and the second metal layer 24 containing, e.g., Ti prior to the Ni layer.

### Fifth Embodiment

FIG. 44 is a sectional view taken along line A-A′ of a semiconductor device 100 according to a fifth embodiment. That is, FIG. 44 is a sectional view of a region 504 corresponding to the region 104 in the first embodiment. In the present embodiment, a portion, provided between a plurality of well layers 7 formed in a semiconductor substrate, of a gate insulating film 9 is thicker than a different portion of the gate insulating film 9. That is, the gate insulating film 9 has a thick oxide film portion 35 immediately above a JFET doped layer 8. Other components are the same as those in the second embodiment.

The thick oxide film portion 35 allows reduction in a feedback capacitance formed by a gate electrode 10 and the JFET doped layer 8 connected to a drain layer. Thus, further speed-up is possible.

### Sixth Embodiment

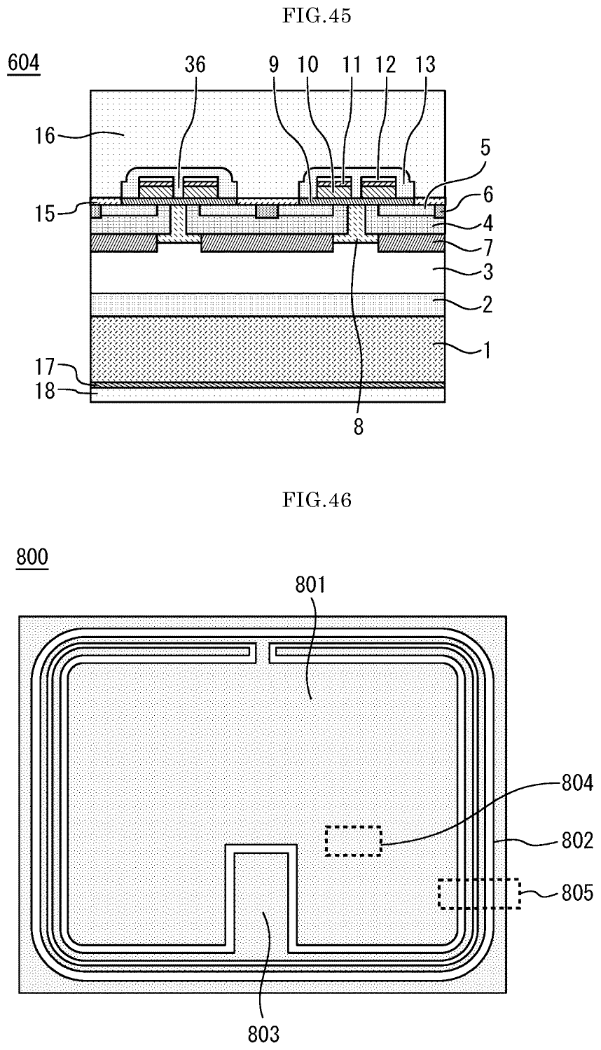

FIG. 45 is a sectional view taken along line A-A′ of a semiconductor device 100 according to a sixth embodiment. That is, FIG. 45 is a sectional view of a region 604 corresponding to the region 104 in the first embodiment. A gate electrode 10 of the present embodiment ends off immediately above a portion between a plurality of well layers 7 of a semiconductor substrate. That is, there is a portion 36 immediately above the JFET doped layer 8 where the gate electrode 10, a first metal layer 11, and a second metal layer 12 are not formed. Other components are the same as those in the second embodiment.

The above-described structure allows reduction in the feedback capacitance formed by the gate electrode 10 and the JFET doped layer 8 connected to the drain layer. Thus, further speed-up is possible.

Meanwhile, technical features explained in each embodiment may be appropriately combined to use.

Hereinafter, various aspects of the present disclosure will be collectively described as appendixes.

### APPENDIX 1

A semiconductor device comprising:
a semiconductor substrate;
a gate electrode which is provided above the semiconductor substrate with a gate insulating film intervening between the gate electrode and the semiconductor substrate and is made with polysilicon;
a first metal layer which is provided on the gate electrode;
a second metal layer which is provided on the first metal layer;
a first electrode which is provided above the second metal layer with an interlayer insulating film intervening between the first electrode and the second metal layer; and
a second electrode which is provided on an opposite side of the semiconductor substrate from the first electrode,
wherein at least one of the first metal layer and the second metal layer contains a metal which suppresses movement of a movable ion.

### APPENDIX 2

The semiconductor device according to appendix 1, wherein the metal that suppresses movement of the movable ion is Ti.

### APPENDIX 3

The semiconductor device according to appendix 2, wherein the first metal layer is made with Ti silicide, and
the second metal layer is made with TiN.

### APPENDIX 4

The semiconductor device according to any one of appendixes 1 to 3, wherein a surface on an opposite side of the second metal layer from the semiconductor substrate is fully covered with the interlayer insulating film in an active region.

### APPENDIX 5

The semiconductor device according to any one of appendixes 1 to 4, comprising gate wiring which is provided above the second metal layer, is electrically connected to the second metal layer, and contains Al.

### APPENDIX 6

The semiconductor device according to any one of appendixes 1 to 4, wherein a gate electrode structure including the gate electrode, the first metal layer, and the second metal layer is extended to a peripheral portion around an active region, and
the semiconductor device comprises gate wiring which is provided above the second metal layer and is electrically connected to the second metal layer at the peripheral portion.

### APPENDIX 7

The semiconductor device according to any one of appendixes 1 to 4, comprising
gate wiring which is provided above the second metal layer and is electrically connected to the second metal layer, wherein
the gate wiring is provided farther from a center of the semiconductor substrate than, of a portion where the first electrode and the semiconductor substrate are electrically connected, a portion farthest from a center of an active region is.

### APPENDIX 8

The semiconductor device according to any one of appendixes 1 to 4, comprising
a barrier metal layer containing a metal which suppresses movement of a movable ion between the interlayer insulating film and the first electrode.

### APPENDIX 9

The semiconductor device according to appendix 8, wherein the metal that suppresses movement of the movable ion is Ti.

### APPENDIX 10

The semiconductor device according to appendix 8 or 9, comprising
gate wiring which is provided above the second metal layer and is electrically connected to the second metal layer, wherein
the barrier metal layer is in contact with the second metal layer and connects the gate wiring and the second metal layer together.

### APPENDIX 11

The semiconductor device according to any one of appendixes 1 to 4, comprising
gate wiring which is provided above the second metal layer and is electrically connected to the second metal layer, wherein
a metal layer which is in contact with the second metal layer and connects the gate wiring and the second metal layer together and a metal layer which is in contact with the semiconductor substrate and connects the first electrode and the semiconductor substrate together are made with a same metal.

### APPENDIX 12

The semiconductor device according to appendix 11, wherein the metal layer that is in contact with the second metal layer and connects the gate wiring and the second metal layer together and the metal layer that is in contact with the semiconductor substrate and connects the first electrode and the semiconductor substrate together contain Ni.

### APPENDIX 13

The semiconductor device according to appendix 11, wherein the metal that is in contact with the second metal layer and connects the gate wiring and the second metal layer together and the metal layer that is in contact with the semiconductor substrate and connects the first electrode and the semiconductor substrate together contain Ti.

### APPENDIX 14

The semiconductor device according to any one of appendixes 1 to 13, wherein a surface on an opposite side from the semiconductor substrate and a side surface of the gate electrode are covered with the first metal layer.

### APPENDIX 15

The semiconductor device according to any one of appendixes 1 to 14, wherein a plurality of wells are formed in the semiconductor substrate, and
a portion which is provided between the plurality of wells of the gate insulating film is thicker than a different portion of the gate insulating film.

### APPENDIX 16

The semiconductor device according to any one of appendixes 1 to 14, wherein a plurality of wells are formed in the semiconductor substrate, and
the gate electrode ends off immediately above a portion between the plurality of wells of the semiconductor substrate.

### APPENDIX 17

The semiconductor device according to any one of appendixes 1 to 16, wherein the semiconductor substrate is made with wide bandgap semiconductor.

### APPENDIX 18

The semiconductor device according to appendix 17, wherein the wide bandgap semiconductor is silicon carbide, a gallium nitride-based material or diamond.

### APPENDIX 19

A method for manufacturing a semiconductor device, the method comprising:
forming a gate electrode above a semiconductor substrate with a gate insulating film intervening between the gate electrode and the semiconductor substrate, using polysilicon;
forming a first metal layer on the gate electrode;
forming a second metal layer on the first metal layer;
forming a first electrode above the second metal layer with an interlayer insulating film intervening between the first electrode and the second metal layer; and
forming a second electrode on an opposite side of the semiconductor substrate from the first electrode, wherein
at least one of the first metal layer and the second metal layer contains a metal which suppresses movement of a movable ion.

### APPENDIX 20

The method for manufacturing the semiconductor device according to appendixes 19, the method comprising
forming a metal layer which is to come into contact with the semiconductor substrate to connect the first electrode and the semiconductor substrate together is formed after the first metal layer and the second metal layer are formed, and
forming gate wiring which is electrically connected to the second metal layer, above the second metal layer.

The semiconductor device and the method for manufacturing the semiconductor device according to the present disclosure can reduce a gate wiring resistance with the first metal layer and the second metal layer. At least one of the first metal layer and the second metal layer contains the metal that suppresses movement of the movable ion, thereby suppressing a threshold shift.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-015648, filed on Feb. 5, 2024 including specification, claims, drawings and summary, on which the Convention priority of the present application is based, are incorporated herein by reference in its entirety.

1. A semiconductor device comprising:
a semiconductor substrate;
a gate electrode which is provided above the semiconductor substrate with a gate insulating film intervening between the gate electrode and the semiconductor substrate and is made with polysilicon;
a first metal layer which is provided on the gate electrode;
a second metal layer which is provided on the first metal layer;
a first electrode which is provided above the second metal layer with an interlayer insulating film intervening between the first electrode and the second metal layer; and
a second electrode which is provided on an opposite side of the semiconductor substrate from the first electrode,
wherein at least one of the first metal layer and the second metal layer contains a metal which suppresses movement of a movable ion.

2. The semiconductor device according to claim 1, wherein the metal that suppresses movement of the movable ion is Ti.

3. The semiconductor device according to claim 2, wherein the first metal layer is made with Ti silicide, and
the second metal layer is made with TiN.

4. The semiconductor device according to claim 1, wherein a surface on an opposite side of the second metal layer from the semiconductor substrate is fully covered with the interlayer insulating film in an active region.

5. The semiconductor device according to claim 1, comprising gate wiring which is provided above the second metal layer, is electrically connected to the second metal layer, and contains Al.

6. The semiconductor device according to claim 1, wherein a gate electrode structure including the gate electrode, the first metal layer, and the second metal layer is extended to a peripheral portion around an active region, and
the semiconductor device comprises gate wiring which is provided above the second metal layer and is electrically connected to the second metal layer at the peripheral portion.

7. The semiconductor device according to claim 1, comprising
gate wiring which is provided above the second metal layer and is electrically connected to the second metal layer, wherein
the gate wiring is provided farther from a center of the semiconductor substrate than, of a portion where the first electrode and the semiconductor substrate are electrically connected, a portion farthest from a center of an active region is.

8. The semiconductor device according to claim 1, comprising
a barrier metal layer containing a metal which suppresses movement of a movable ion between the interlayer insulating film and the first electrode.

9. The semiconductor device according to claim 8, wherein the metal that suppresses movement of the movable ion is Ti.

10. The semiconductor device according to claim 8, comprising
gate wiring which is provided above the second metal layer and is electrically connected to the second metal layer, wherein
the barrier metal layer is in contact with the second metal layer and connects the gate wiring and the second metal layer together.

11. The semiconductor device according to claim 1, comprising
gate wiring which is provided above the second metal layer and is electrically connected to the second metal layer, wherein
a metal layer which is in contact with the second metal layer and connects the gate wiring and the second metal layer together and a metal layer which is in contact with the semiconductor substrate and connects the first electrode and the semiconductor substrate together are made with a same metal.

12. The semiconductor device according to claim 11, wherein the metal layer that is in contact with the second metal layer and connects the gate wiring and the second metal layer together and the metal layer that is in contact with the semiconductor substrate and connects the first electrode and the semiconductor substrate together contain Ni.

13. The semiconductor device according to claim 11, wherein the metal that is in contact with the second metal layer and connects the gate wiring and the second metal layer together and the metal layer that is in contact with the semiconductor substrate and connects the first electrode and the semiconductor substrate together contain Ti.

14. The semiconductor device according to claim 1, wherein a surface on an opposite side from the semiconductor substrate and a side surface of the gate electrode are covered with the first metal layer.

15. The semiconductor device according to claim 1, wherein a plurality of wells are formed in the semiconductor substrate, and
a portion which is provided between the plurality of wells of the gate insulating film is thicker than a different portion of the gate insulating film.

16. The semiconductor device according to claim 1, wherein a plurality of wells are formed in the semiconductor substrate, and
the gate electrode ends off immediately above a portion between the plurality of wells of the semiconductor substrate.

17. The semiconductor device according to claim 1, wherein the semiconductor substrate is made with wide bandgap semiconductor.

18. The semiconductor device according to claim 17, wherein the wide bandgap semiconductor is silicon carbide, a gallium nitride-based material or diamond.

19. A method for manufacturing a semiconductor device, the method comprising:
forming a gate electrode above a semiconductor substrate with a gate insulating film intervening between the gate electrode and the semiconductor substrate, using polysilicon;
forming a first metal layer on the gate electrode;
forming a second metal layer on the first metal layer;
forming a first electrode above the second metal layer with an interlayer insulating film intervening between the first electrode and the second metal layer; and
forming a second electrode on an opposite side of the semiconductor substrate from the first electrode, wherein
at least one of the first metal layer and the second metal layer contains a metal which suppresses movement of a movable ion.

20. The method for manufacturing the semiconductor device according to claim 19, the method comprising
forming a metal layer which is to come into contact with the semiconductor substrate to connect the first electrode and the semiconductor substrate together is formed after the first metal layer and the second metal layer are formed, and
forming gate wiring which is electrically connected to the second metal layer, above the second metal layer.
